(19) United States
(12) Patent Application Publication
(10) Pub. No.: US 2003/0129798 A1
(43) Pub. Date: Jul. 10, 2003

(54) Fabrication of low-resistance electrodes in a deep trench using electrochemical methods

(76) Inventors: Annette Saenger, Dresden (DE); Bernhard Sell, Portland, OR (US); Albert Birner, Dresden (DE); Matthias Goldbach, Dresden (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/324,434

(22) Filed: Dec. 20, 2002

(30) Foreign Application Priority Data
Dec. 20, 2001 (DE) 101 62 900.1

(51) Int. Cl. H01L 21/8242

(52) U.S. Cl. 438/243

(57) ABSTRACT

The invention relates to a method for fabricating low-resistance electrodes in trench capacitors, and includes steps of: providing a wafer; producing trenches in the wafer; introducing the wafer into an electrolyte solution including a salt of an electrically conductive material; and electrically contact-connecting the wafer and applying a voltage between the wafer and a counterelectrode configured in the electrolyte solution to electrodeposit at least sections of the electrically conductive material in the trenches. The electrodeposition of the electrode material enables a uniform layer thickness along all regions of the trench wall.

### BACKGROUND OF THE INVENTION

Field of the Invention

The invention relates to a method for fabricating low-resistance electrodes in trench capacitors.

Economic success in the semiconductor industry is essentially influenced by continuing to further reduce the minimum feature size that is produced on a microchip. Reducing the minimum feature size makes it possible to increase the integration density of the electronic components such as transistors or capacitors on the microchip, and thus to increase the computing speed of processors and also to increase the storage capacity of memory modules. To enable the area required by the components on the chip surface to be kept small, the depth of the substrate is also utilized in the case of capacitors. To that end, first a trench is introduced into the wafer. Afterward, a bottom electrode is produced, for example, by doping the regions of the wafer that adjoin the wall of the trench in order to increase the electrical conductivity. A thin layer of a dielectric is then applied to the bottom electrode. Finally, the trench is filled with an electrically conductive material in order to obtain a counterelectrode. The counterelectrode is also referred to as top electrode. This arrangement of electrodes and dielectric means that the capacitor is, as it were, folded. Given electrode areas of constant size, that is to say of the same capacitance, the lateral extent of the capacitor on the chip surface can be minimized. Such capacitors are also referred to as “deep trench” capacitors.

In memory chips, the charge and discharge states of the capacitor correspond to the two binary states 0 and 1. In order to be able to reliably determine the charge state of the capacitor, and thus the information stored in the capacitor, the capacitor must have a specific minimum capacitance. If the capacitance, or in the case of a partly discharged capacitor, the charge falls below a limit value, the signal disappears in the noise. That is to say the information about the charge state of the capacitor is lost. After writing, the capacitor is discharged by leakage currents that bring about a charge balancing between the two electrodes of the capacitor. With decreasing dimensions, the leakage currents increase since tunneling effects gain in importance. In order to counteract a loss of information through the discharge of the capacitor, the charge state of the capacitor is checked at regular intervals and if appropriate refreshed, that is to say a partly discharged capacitor is charged again up to its original state. However, technical limits are imposed on these so-called “refreshing” times—that is to say they cannot be shortened arbitrarily. During the period of the refreshing time, therefore, the charge of the capacitor is permitted to decrease only to an extent such that a reliable determination of the charge state is possible. For a given leakage current, the capacitor must therefore have a specific minimum charge at the beginning of the refreshing time, so that, at the end of the refreshing time, the charge state is still high enough above the noise to reliably read out the information stored in the capacitor. In order to be able to combat the difficulties arising as a result of the advancing miniaturization, a multiplicity of solution approaches are being pursued. Thus, by way of example, the surface of the electrodes is provided with a structure so that, as the length and width of the electrodes decrease, the surface thereof is made as large as possible. Furthermore, new materials are being used. Thus, attempts are being made to replace silicon dioxide, which has been used hitherto as a dielectric, by materials with a higher dielectric constant.

As electrode material, polysilicon is currently used to fill the trench. With further miniaturization, i.e. a smaller diameter of the trench, the layer thickness of the conductive material decreases, so that the electrical conductivity of the polysilicon no longer suffices to provide the required charge. In order to combat a loss of capacitance of the capacitors in the context of advancing miniaturization, electrodes made of metals having higher electrical conductivity, for example, platinum, are used instead of the currently used electrodes made of doped polysilicon. As a result, it is possible to suppress depletion zones in the electrodes and thus to fabricate thinner electrodes which nevertheless provide the required charge density on the electrodes.

U.S. Pat. No. 5,905,279 describes a trench capacitor in which, in addition to polysilicon, further electrically conductive materials, such as WSi, TiSi, W, Ti and TiN, are also used to fill the trenches.

Trench capacitors have a very high aspect ratio of usually more than 60. The term aspect ratio denotes the ratio of the extent of the capacitor in its longitudinal direction, which is into the depth of the substrate, to the diameter of the opening of the capacitor at the surface of the substrate. The high aspect ratio leads to difficulties in constructing the trench capacitor. A trench that has been introduced into the wafer for constructing a trench capacitor has a very small opening at the substrate surface, through which substances can be transported into the trench in order to be deposited there, but, on the other hand, a very large extent into the depth of the substrate, in which case the material to be deposited has to be able to penetrate down to the bottom of the trench. During the deposition of layers in the trench, for example, in order to produce a dielectric arranged between the bottom electrode and the top electrode, the layer thickness is intended to be as uniform as possible in the entire trench. An edge covering of 1 is desired. The edge covering denotes the ratio of the layer thickness at the bottom of the trench to the layer thickness at the upper opening of the trench. Only a few methods are suitable for fabricating such layers. The deposition is usually effected using a CVD (CVD=Chemical Vapor Deposition) or ALD (ALD=Atomic Layer Deposition) method. In this case, gaseous precursors are used that are converted into the desired compounds at the substrate surface. In the CVD method, the reactants are simultaneously situated in the gas space above the substrate. The material to be deposited is deposited as a result of the conversion of the reactants on the substrate surface. With this method, relatively thick layers can be produced in comparatively short times, but fluctuations in the layer thickness have to be accepted. In the ALD method, the layer is constructed by depositing individual layers of the various reactants. Thus, only one reactant is situated in the gas space above the substrate, and is deposited in a monomolecular layer on the substrate. Afterward, excess reactant is removed from the gas space, for example, by pumping away or flushing with an inert gas, after which a further reactant is introduced into the gas space above the substrate. The further reactant reacts with the reactant previously bonded as a monomolecular layer on the substrate, and likewise forms a monomolecular layer. This makes it possible to fabricate uniform layers with a defined layer thickness. Both CVD and ALD methods require gaseous reactants. Furthermore, on the one hand the reactants must be sufficiently reactive to be able to produce a layer in tenable process times; on the other hand the reactants must also be stable enough not to decompose before the actual deposition. In the case of the ALD method, the reactant must be able to form a monomolecular layer that remains stable until the deposition of the further reactant. This greatly restricts the selection of the reactants. Such precursor compounds are not available for a relatively large number of metals. Furthermore, the reaction products liberated during the reaction of the reactants must not attack the substrate. Thus, by way of example, WF₆ as a gaseous precursor compound is ruled out for fabricating thin tungsten layers on a silicon substrate, since fluorine is liberated during the conversion to form the tungsten metal, which fluorine attacks the silicon of the substrate. A further disadvantage of the method outlined is that in the CVD and ALD methods, the reaction product is deposited on the entire wafer surface and not just in the trenches. After deposition, the layer produced therefore has to be patterned, i.e. excess material has to be removed again from the substrate surface.

### SUMMARY OF THE INVENTION

It is accordingly an object of the invention to provide a method for fabricating low resistance electrodes in trench capacitors, which overcome the above-mentioned disadvantages of the prior art methods of this general type.

In particular, it is an object of the invention to provide a method for fabricating low-resistance electrodes in trench capacitors that is simple to carry out, that enables selective deposition to be obtained only in the desired regions, and that makes it possible to fabricate uniform thin layers made of a wide variety of metals even in trenches with a high aspect ratio.

With the foregoing and other objects in view there is provided, in accordance with the invention, a method for fabricating low-resistance electrodes in trench capacitors. The method includes steps of: providing a wafer; producing trenches in the wafer; introducing the wafer into an electrolyte solution including a salt of an electrically conductive material; and electrically contact-connecting the wafer and applying a voltage between the wafer and a counterelectrode configured in the electrolyte solution to electrodeposit at least sections of the electrically conductive material in the trenches.

In accordance with an added feature of the invention, the trenches have an aspect ratio of at least 40.

In accordance with an additional feature of the invention, the method includes doping at least sections of the wafer adjacent the trenches to increase an electrical conductivity of the sections.

In accordance with another feature of the invention, the method includes introducing at least sections of an electrically conductive initial layer into the trenches before performing the step of electrodepositing at least sections of the electrically conductive material in the trenches.

In accordance with a further feature of the invention, a chemical vapor deposition method or an atomic layer deposition method is used to perform the step of introducing at least sections of the electrically conductive initial layer into the trenches.

In accordance with a further added feature of the invention, the method includes: lengthening the initial layer to form a contact area; and using the contact area when performing the step of electrically contact-connecting the wafer.

In accordance with a further additional feature of the invention, the method includes: first depositing a layer of a dielectric in the trenches, and then depositing an electrically conductive initial layer on the layer of the dielectric; and performing the step of electrically contact-connecting the wafer by electrically contact-connecting the electrically conductive initial layer and electrodepositing the electrically conductive material on the initial layer.

In accordance with yet an added feature of the invention, the step of electrically contact-connecting the wafer includes electrically contact-connecting a rear side of the wafer.

In accordance with yet another feature of the invention, conductive material is a metal.

The method is carried out such that first trenches are introduced into a wafer by customary methods. To that end, first various layers can be applied on the wafer, e.g. insulating layers, in order to be able to carry out the electrodeposition only in selected sections of the wafer, for example in the trenches. Layers for patterning are then deposited on the wafer, for which purpose, by way of example, first a layer made of an etching-stable material can be deposited, such as, silicon dioxide or a borosilicate glass. Afterward, a photoresist is applied, exposed in sections through a mask, and then developed in order to define the regions to be etched. The trenches are then etched into the wafer. The walls of the trenches can also be modified, for example by being covered with an insulating layer in sections. In this way, the wafer can be modified such that the electrically conductive material is deposited only in the desired sections of the trenches, while the remaining sections are covered by an insulating layer, that is to say electrodeposition cannot take place in them. If necessary, the wafer can also be modified in such a way that it is possible to produce an electrical contact with the sections in which the electrically conductive material is intended to be electrodeposited. If the wafer has a sufficiently high bulk conductivity, it can be contact-connected from its rear side. This can be done over the whole area, for example, via a plate or a grid, or else in point form via a contact finger. The front side of the wafer can also be electrically contact-connected if the wafer has an excessively low electrical conductivity or the region in which the electrically conductive material is intended to be deposited is electrically insulated from the wafer, for example, because an insulating dielectric has already been deposited in the trench. In this case, the wafer must have a sufficiently high electrical conductivity along its surface. For the electrodeposition of the electrically conductive compound, the wafer is then passed into an electrolyte solution. The latter contains a salt of the electrically conductive material to be deposited dissolved in a suitable solvent. The electrolyte solution may also contain further additives that can have a positive influence on the electrodeposition of the electrically conductive material or the properties of the deposited electrically conductive material. The electrically conductive material is generally a metal. In contrast to the reactants that can be used for CVD and ALD methods, a large multiplicity of suitable salts are available for the electrodeposition of metals. The electrodeposition of metals has already been used for a long time in other areas and is also used in semiconductor manufacturing, for example, for fabricating copper interconnects. Therefore, experience for the process implementation is already available and can be transferred to the fabrication of electrodes for trench capacitors. The salt of the metal to be deposited is dissolved in a suitable solvent. Aqueous solutions are used in the simplest case; however, it is also possible to use organic solvents provided that the latter produce a sufficiently high ionic conductivity. Examples of such solvents are dimethylformamide, dimethyl sulfoxide, acetonitrile, POCl₃, SOCl₂, SO₂Cl₂, dimethoxyethane or else hexamethyl-phosphoric triamide. The corresponding safety precautions must be observed in the implementation. The concentration of the metal salt is typically between 0.02 and 1 mol/l. If the intention is to fabricate electrodes made of copper, it is possible, for example, to use a solution containing 55 to 65 g/l copper sulfate, 200 to 250 g/l sulfuric acid and 40-60 ppm chloride ions. For other metals, solutions having comparable concentrations of the metal salt are used. Furthermore, a counterelectrode is arranged in the electrodeposition bath. The counterelectrode may be configured as an inert electrode and be composed, for example, of platinum or graphite, or else be a sacrificial anode composed of the metal to be deposited or an alloy thereof. A voltage is applied between the wafer and the counterelectrode. The magnitude of the voltage is dependent, inter alia, on the metal to be deposited and the solvent system used. The wafer is generally connected cathodically. The applied voltage may be up to 2.5 volts, for example, at a current density of 15 to 25 mA/cm². The electrodeposition leads to a uniform deposition of the metal, so that a good edge covering is achieved even in trenches with a high aspect ratio of 40 or more.

If the wafer does not have a sufficiently high electrical conductivity, the wafer can be doped before the electrodeposition at least in sections of the trenches in order to increase the electrical conductivity. In this case, the doping is effected by customary methods. A gas phase doping is preferably carried out, in the case of which the dopant is introduced into the material of the wafer by way of the gas phase. This has the advantage that excess dopant can easily be removed.

It may also be advantageous if an electrically conductive initial layer is introduced into the trenches at least in sections before the electrodeposition of the electrically conductive material. This is necessary in particular when a layer of a dielectric, which layer electrically insulates the inner wall of the trench from the wafer, has already been deposited in the trench. The conductive initial layer may be composed of a metal, for example tungsten or titanium, or else a metal-containing compound, such as TiN.

The initial layer is produced by a different method than electrodeposition. In order to achieve a uniform layer thickness for the initial layer, the initial layer is preferably deposited by a CVD or ALD method.

The material of the initial layer and the electrodeposited electrically conductive material may be identical or different. In the former case, the layer is thickened as a result of the electrodeposition, while in the latter case the initial layer can also act as a dopant for the electrically conductive material or the material of the electrode is only formed later from the material of the initial layer and the deposited electrically conductive material. To that end, the initial layer is composed of a first material and a layer made of a second material is electrodeposited on the first material. A heat treatment step is subsequently carried out, so that the electrically conductive material of the electrode is formed from the first material and the second material. By way of example, a layer of polysilicon can be deposited as the initial layer. A metal layer is subsequently electrodeposited on the layer of polysilicon. A metal silicide may subsequently be produced by heat treatment. The heat treatment is preferably effected at temperatures of more than 500° C.

In order to be able to provide a sufficient electrical contact, the initial layer may be lengthened to form a contact area. The electrical contact connection of the wafer may then be connected via the contact area. To that end, the fabrication of the initial layer may be configured in such a way that electrically conductive regions are provided around the opening of the trench and the electrical contact is then produced by a contact finger to the regions.

The inventive method is suitable both for fabricating top electrodes and for fabricating bottom electrodes. During the fabrication of top electrodes, first a layer of a dielectric is deposited in the trenches. An electrically conductive initial layer is subsequently deposited on the layer of the dielectric and the electrically conductive initial layer is then electrically contact-connected. Finally, the electrically conductive material is electrodeposited on the initial layer.

In accordance with a preferred embodiment, the rear side of the wafer is electrically contact-connected. This embodiment is particularly suitable for fabricating bottom electrodes, the metal of the electrode being deposited in the trenches directly on the silicon of the wafer. In this case, the front side of the wafer may also be covered with an electrically insulating material.

The conductive material is preferably a metal. Examples of suitable metals are copper, tungsten, titanium, tantalum, platinum, palladium or else rhodium.

Other features which are considered as characteristic for the invention are set forth in the appended claims.

Although the invention is illustrated and described herein as embodied in a fabrication of low-resistance electrodes in the deep trench by means of electrochemical methods, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1A and 1B show steps for fabricating a trench for a deep trench capacitor in a silicon substrate;

FIGS. 2A and 2B show steps for fabricating a top electrode embodied as a metal electrode;

FIGS. 3A and 3B show steps for fabricating a top electrode embodied as a metal silicide electrode;

FIGS. 4A and 4B show steps for fabricating a DRAM;

FIGS. 5A and 5B show steps for preparing the trench for a deep trench capacitor in an SOI substrate;

FIGS. 6A and 6B show steps for fabricating a top electrode embodied as a metal electrode;

FIGS. 7A and 7B show steps for fabricating a top electrode embodied as a metal silicide electrode;

FIG. 8 is a view of a detail from a completed DRAM; and

FIGS. 9A and 9B show work steps for fabricating a bottom electrode.

### DESCRIPTION OF THE PREFERRED EMBODIMENTS

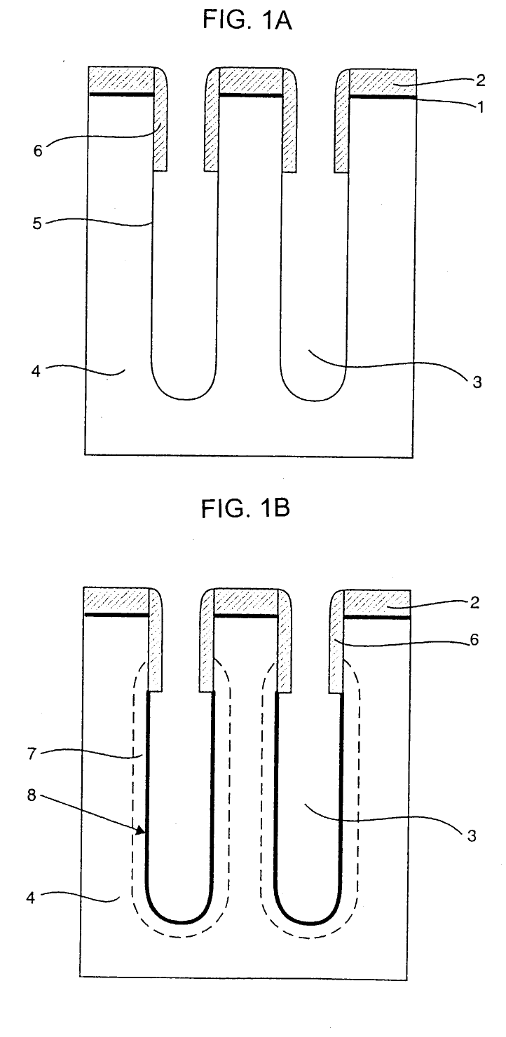

In order to produce trenches, first the surface of a silicon wafer is oxidized in an oxygen atmosphere in order to produce a thin oxide layer having a thickness of about 5 nm. This thin oxide layer is designated by the reference symbol 1 in FIG. 1A. The oxidation first reduces stresses in the wafer and second provides an adhesion layer for further layers. A nitride layer having a thickness of approximately 200 nm is subsequently deposited onto the oxide layer 1 by a CVD method, which nitride layer is designated by the reference symbol 2 in FIG. 1A. For patterning the nitride layer 2, first a layer made of a hard mask material, for example, a borosilicate glass, is then deposited. A photoresist is subsequently applied, exposed in sections using a mask and is developed using a developer in order to define openings with a diameter of approximately 100 nm for the trenches. The openings are then transferred into the layer of the hard mask using a fluorine-containing plasma, and the corresponding regions of the nitride layer 2 are also removed at the same time. After removing the photoresist layer, the trench 3 is etched into the silicon substrate or wafer 4 down to a depth of approximately 8 μm using a further fluorohydrocarbon plasma. Finally, the hard mask is removed using hydrofluoric acid, for example. The silicon wafer then has, on its surface, a nitride layer 2 applied on the thin oxide layer 1, and also trenches 3. The walls 5 of the trenches 3 are formed from the silicon of the wafer. For further processing, first a thin oxide layer, having a thickness of approximately 10 nm, is produced on the wall 5 of the trenches 3 by thermally oxidizing the uncovered silicon with oxygen. Polysilicon is subsequently deposited on the wafer, so that the trench 3 is completely filled with polysilicon. The polysilicon is etched back anisotropically in order to remove the polysilicon from the surface of the wafer and also in the upper section of the trenches 3 down to a depth of approximately 1 μm. The uncovered oxide layer can then be etched away isotropically at the sections that are uncovered in the upper region of the trench wall 5. An insulating layer 6 made of an oxide/nitride film and having a thickness of approximately 20 nm is then deposited and the oxide/nitride film is subsequently etched anisotropically, so that the surface of the polysilicon previously deposited in the trenches 3 is uncovered again. The polysilicon still present in the trenches 3 is removed by isotropic etching, so that the trenches 3 are again uncovered down to their entire depth. The arrangement shown in FIG. 1A is obtained once the thin oxide film produced below the polysilicon at the wall of the trench 3 has also been removed by isotropic etching, for example using hydrofluoric acid. FIG. 1A shows a detail from a wafer 4 having trenches 3 configured therein. In the lower section of the trench 3, the silicon of the wafer 4 is uncovered at the wall 5. On the top side of the wafer 4, a layer 2 made of a nitride is arranged on a thin oxide layer 1. In the upper section of the trench 3, the wall is lined with a nitride layer 6 in collar form. In order to improve the conductivity, the regions of the silicon wafer 4 which are uncovered in the trenches 3 are then doped. This can be done, for example, with gas phase doping using arsine. However, other doping methods can likewise be employed. In region 7, illustrated by broken lines in FIG. 1B, the silicon then has an increased electrical conductivity. Together with the silicon substrate 4, this region acts as bottom electrode in the completed capacitor. A nitride/oxide layer 8 having a thickness of approximately 5 nm is then deposited as a dielectric. The arrangement illustrated in FIG. 1B is thus obtained. The trenches 3 introduced into the wafer 4 are lined with a thicker layer 6 made of an insulating oxide/nitride in their upper section and with a thinner layer 8 of the nitride/oxide dielectric in their lower section. The region 7 of the wafer 4 forming the bottom electrode is doped in order to increase the electrical conductivity. The upper side of the wafer 4 is covered with an insulating nitride layer 2. In order to be able to fabricate a top electrode in the trenches 3, it is now necessary first to increase the electrical conductivity at the surface of the wafer 4.

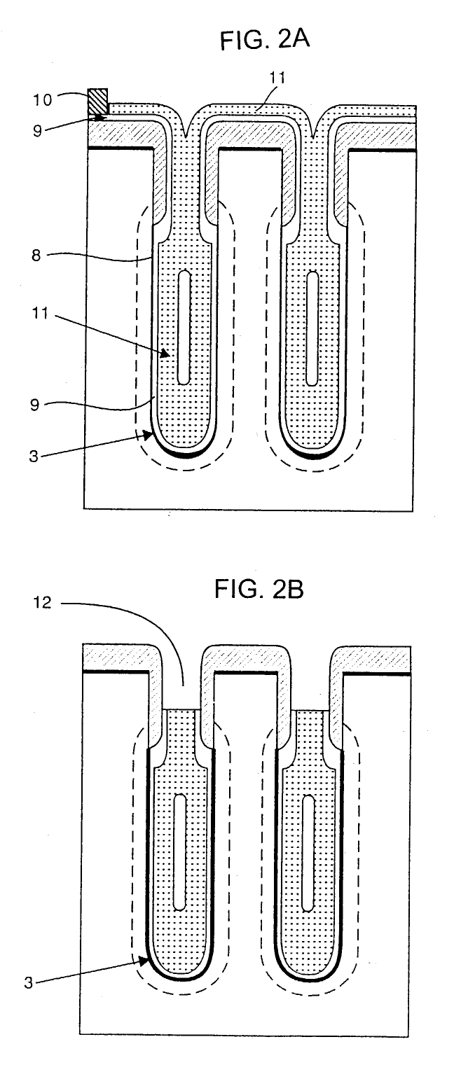

FIGS. 2A and 2B show the work steps for fabricating a metal electrode. Firstly, a thin electrically conductive layer 9 made of the metal, for example, tungsten is deposited on the dielectric 8 as an initial layer, in order to increase the electrical conductivity. The tungsten is deposited using a CVD (Chemical Vapor Deposition) or ALD (Atomic Layer Deposition) method. In this case, the layer thickness of the deposited electrically conductive layer 9 is chosen to be large enough that a sufficient electrical conductivity is available for the subsequent metal electrodeposition. By way of example, a layer thickness of approximately 10 nm is suitable. The electrically conductive metal layer 9 is electrically contact-connected via the contact 10. The contact 10 can be chosen in accordance with the design of the wafer and may be effected, for example, annularly around the opening of a trench 3 or by using a contact finger. The wafer is then passed into an electrodeposition bath in which a salt of the metal to be deposited, for example, a tungstate, is dissolved in a suitable solvent. Further auxiliaries may also be admixed with the bath. Depending on the metal to be deposited and the solvent used, the applied voltage may be up to 2.5 volts at a current density of 15-25 mA/cm². The layer thickness of the deposited metal layer 11 is generally between 20 and 200 nm. Finally, for the further process steps for fabricating a DRAM, the metal layers 9 and 11 are etched back again isotropically in the upper region 12 of the trench 3. In the case of tungsten, this may be done for example by isotropic etching-back using a fluorine plasma. The arrangement illustrated in FIG. 2B is obtained. The further construction of the DRAM takes place in section 12.

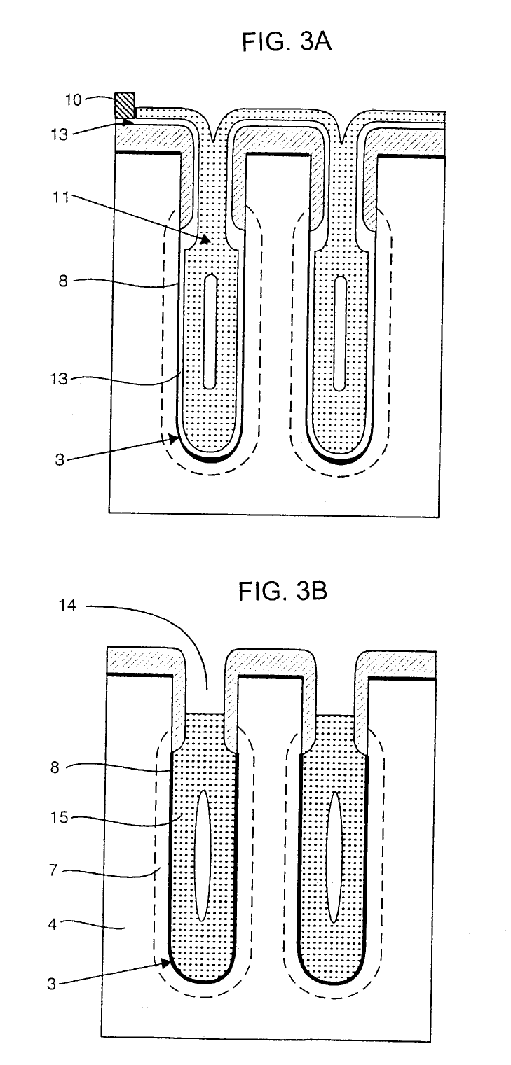

The sequences during the fabrication of a top electrode embodied as a metal silicide electrode are illustrated in FIGS. 3A and 3B. Proceeding from the construction shown in FIG. 1B, first a thin layer 13 made of electrically conductive polysilicon is deposited as an initial layer on the layer 8 of the dielectric by using a CVD method. In this case, it is also possible to introduce a doping into the polysilicon in order to increase the electrical conductivity. The thin polysilicon layer 13 is then electrically contact-connected via contact 10. The prepared wafer is then passed into an electrodeposition bath containing a salt of the metal to be deposited dissolved in a suitable solvent, for example a tungstate, and a voltage is applied between the wafer and a counterelectrode arranged in the electrodeposition bath, so that the metal is deposited as layer 11 on the layer of polysilicon 13. In this case, the trench 3 is filled completely or at least partly with the metal. The wafer is subjected to heat treatment in order to produce the silicide. To that end, the wafer is transferred into a furnace and heated to temperatures of at least 500° C. As a result, the thin polysilicon layer 13 migrates into the electrodeposited metal 11. If tungsten, for example, was electrodeposited as the metal, then WSiₓ forms during the heat treatment, which has an increased thermal stability and can therefore easily be processed, or remains stable, in subsequent processing steps which possibly require high temperatures. A silicon gradient may still remain, depending on the duration of the heat treatment, but such inhomogeneities do not disturb the further processing of the wafer. Finally, the metal silicide is etched back isotropically from the upper side of the wafer and in the upper section 14 of the filling 15 of the metal silicide, for example, by using a dry etching process. The construction shown in FIG. 3B is thus obtained. Doped regions 7 are introduced in the wafer 4, and together with the material of the wafer 4, form the bottom electrode of the capacitor. An insulating layer is applied as the dielectric 8 in the doped regions 4 and the trench 3, and the interior of the trench 3 is filled with a metal silicide 15 which later forms the top electrode of the capacitor.

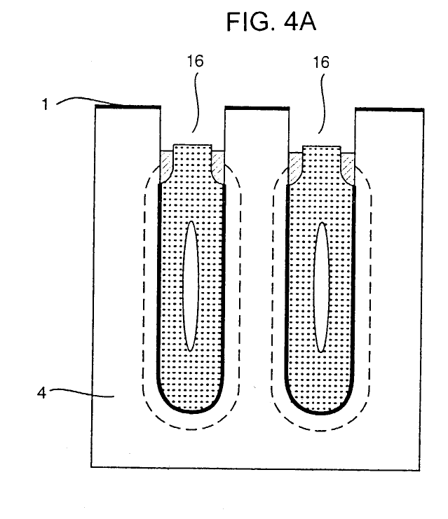

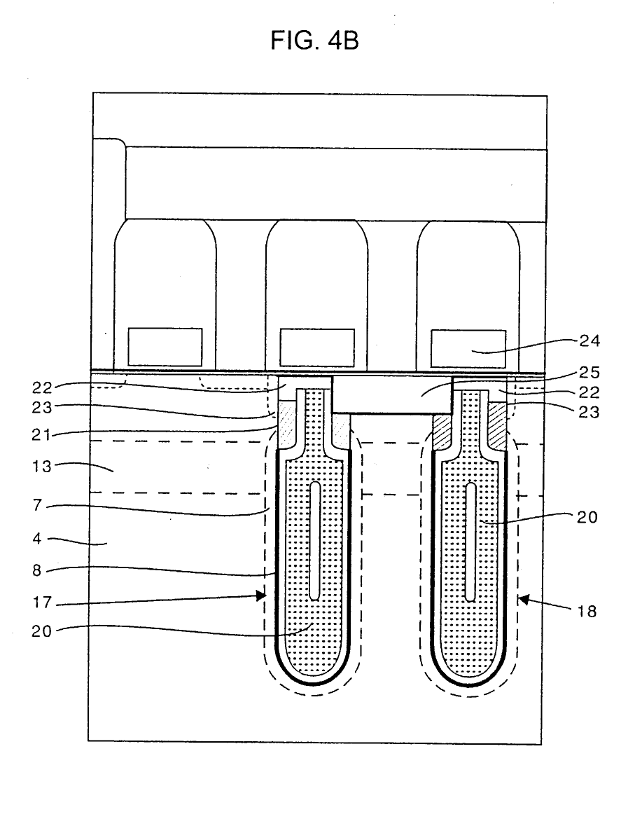

Proceeding from the arrangements shown in FIGS. 2B and 3B, in order to construct the DRAM, first the insulating layer 8 is removed from the upper area of the wafer and in the upper regions 12 and 14 of the trench 3. This can be done, for example, by isotropic etching using phosphoric acid or hydrofluoric acid. The arrangement shown in FIG. 4A is thus obtained. The upper area of the wafer 4 is also covered with an oxide layer 1, while the crystalline silicon of the wafer 4 is uncovered in the upper sections 16 at the walls of the trenches 3. The further elements of a DRAM are subsequently constructed, involving great possibilities for variation. A section through a completed DRAM is shown by way of example in FIG. 4B. The two capacitors 17, 18 have been incorporated into the wafer 4 by the method described above. The doped regions 7, which, together with the wafer substrate, form the bottom electrode, are connected to one another via conduction paths 13 which have been implanted into the wafer 4. The top electrodes 20 are insulated from the electrically conductive regions 7 by means of an insulation collar 21. The electrical connection to the top electrode 20 is effected via an electrical lead 22 made of polysilicon, which produces the connection to an electrically conductive, doped region 23. Via the latter, the top electrode 20 is connected to the base of a field-effect transistor arranged above the storage capacitors 17, 18. By influencing the field acting on the gate 24, the storage capacitor 17, 18 can be charged. Adjacent memory cells are electrically insulated from one another, in each case by means of an oxide layer 25, which is arranged at a so-called “shallow trench” between adjacent memory cells. For the sake of clarity, only two storage capacitors 17, 18, assigned to separate memory cells, have been illustrated. The illustration of a third storage capacitor arranged to the left of the storage capacitor 17 in FIG. 4B has been dispensed with. The capacitor, together with the storage capacitor 17 and the assigned transistors, forms a memory cell.

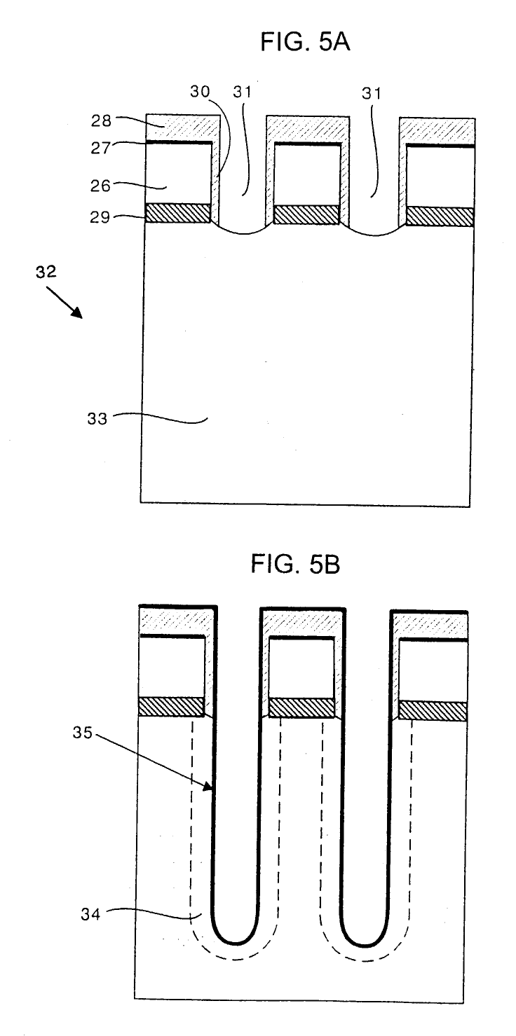

FIGS. 5A to 7B show the fabrication of storage capacitors proceeding from an SOI substrate. An SOI substrate (SOI=“silicon on isolator”) includes two layers made of crystalline silicon which are separated by a layer made of an insulating material, for example an oxide. In a manner comparable to the method sequence portrayed in FIG. 1, first a thin oxide layer 27 is produced on the upper crystalline silicon layer 26 by thermally oxidizing the silicon in an oxygen-containing atmosphere. The oxide layer 27 has a thickness of approximately 10 nm. Afterward, an insulating nitride layer 28 having a thickness of approximately 200 nm is deposited and a layer made of, a borosilicate glass and having a thickness of approximately 1000 nm is deposited on the nitride layer for fabricating a hard mask. The hard mask is patterned by a procedure in which first a layer of a photosensitive resist is applied and is subsequently exposed and developed. In a first anisotropic etching operation, the structure produced in the photoresist is then transferred into the hard mask and afterward, in a second anisotropic etching operation, the structure is transferred into the SOI substrate, the uncovered regions of the nitride layer 28, of the oxide layer 27, of the upper layer 26 made of crystalline silicon, and of the buried oxide layer 29 being removed. Finally, the photoresist layer is also removed from the surface of the SOI substrate. In order to produce the nitride collar 30 illustrated in FIG. 5A, a nitride layer having a thickness of approximately 5 nm is then deposited by a CVD method. The construction illustrated in FIG. 5A is thus obtained. Trenches 31 are introduced into the SOI substrate 32, which trenches extend through the nitride layer 28 arranged on the surface of the substrate, the upper active silicon layer 26, the oxide layer 29 and to the lower crystalline silicon layer 33. The trenches 31 are provided with a nitride layer 30 arranged in collar form at their wall.

In a further anisotropic dry etching step, the trench 31 is then lengthened down to its final depth into the lower silicon layer 33. If necessary, that region of the lower silicon layer 33 which is uncovered in the lower section of the trenches 31 is doped in order to increase the electrical conductivity. This may be done for example by gas phase doping using arsine. The doped regions 34 illustrated in FIG. 5B are thus obtained. After the doping, a thin layer 35 of a nitride/oxide dielectric is deposited, which later forms the dielectric arranged between bottom electrode and top electrode.

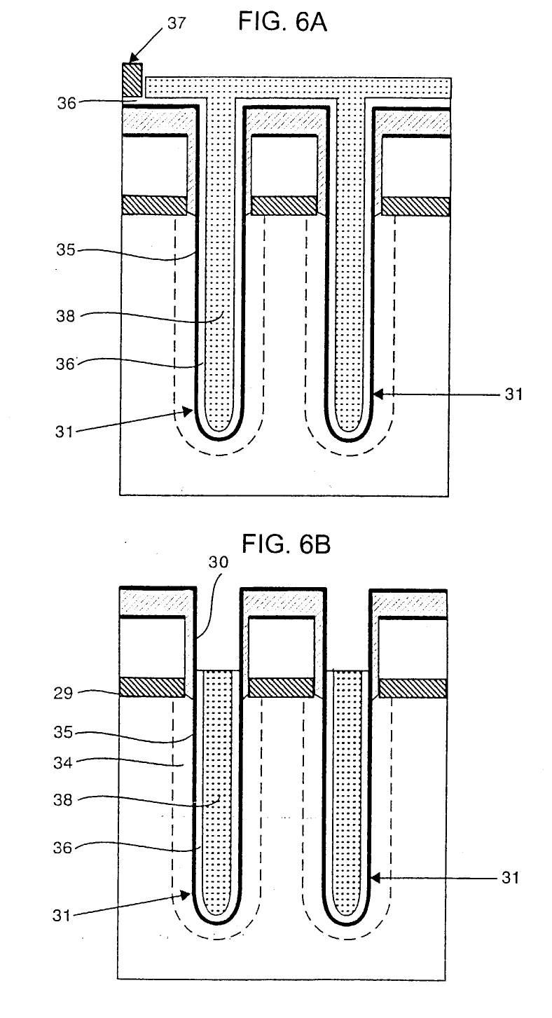

FIGS. 6A and 6B show the further sequence for fabricating a top electrode constructed from a metal, for example tungsten. First, a conductive metal layer 36 having a thickness of approximately 10 nm, which is illustrated in FIG. 6A, is applied on the layer 35 of the dielectric using a CVD or ALD method. The wafer is passed into an electrodeposition bath in which a salt of the metal to be deposited is dissolved in a suitable solvent, and the conductive layer 36 is electrically contact-connected via the contact 37. A voltage is then applied between the contact 37 and a counterelectrode arranged in the electrodeposition bath in order to electrodeposit further metal 38 on the thin conductive layer 36. The arrangement illustrated in FIG. 6A is obtained. The metal 38 has been deposited on the upper area of the wafer and in the trenches. Finally, the metal 36, 38 is removed from the top area of the substrate and from the upper section of the trenches 31 by isotropic etching, so that the arrangement shown in FIG. 6B is obtained. The lower part of the trenches 31 are filled with the metal formed from the layers 36, 38 and which forms the top electrode in the finished capacitor. It is isolated from the doped region 34 of the bottom electrode by the dielectric 35 arranged between the later electrodes. In the upper region of the trenches, the region formed from the layers 36, 38 is insulated by the nitride layer 30 arranged in collar form and the buried oxide layer 29 of the SOI substrate.

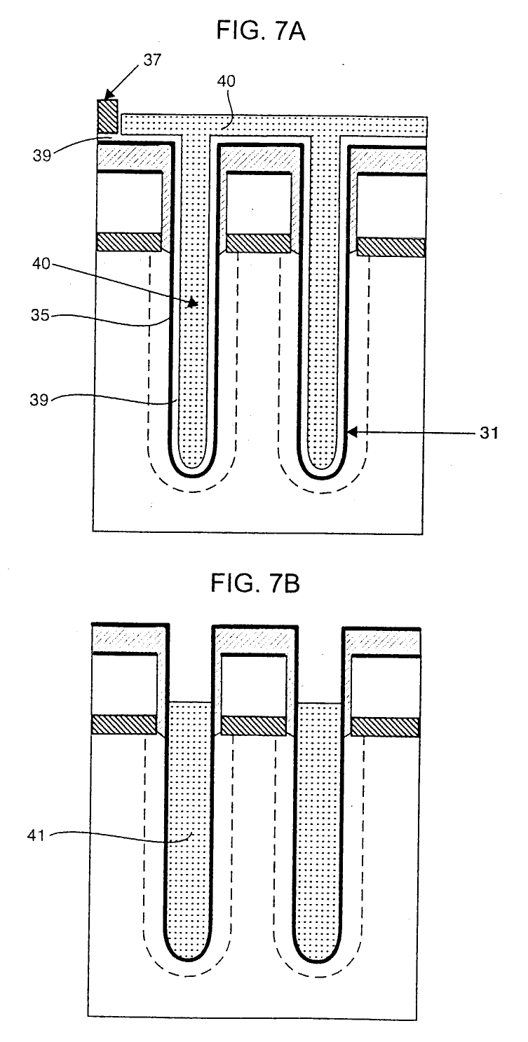

The production, by electrodeposition, of a top electrode composed of a metal silicide is explained with reference to FIGS. 7A and 7B. Proceeding from the arrangement illustrated in FIG. 5B, first a thin layer 39 made of polysilicon is deposited on the layer of the dielectric 35 by a CVD method. In this case, the polysilicon may also already be provided with a suitable doping. The layer 39 is electrically contact-connected via the contact 37 and the wafer is subsequently passed into an electrodeposition bath containing a salt of the metal to be deposited dissolved in a suitable solvent. A voltage is applied between the contact 37 and a counterelectrode arranged in the electrodeposition bath, so that a layer 40 of metal is electrodeposited on the layer 39 made of polysilicon. The arrangement shown in FIG. 7A is obtained after the electrodeposition of the metal layer 40. On the upper side of the SOI substrate and in the interior of the trenches, a metal layer 40 has been deposited on the polysilicon layer 39. A metal silicide 41 is formed from the layers by heat treatment at temperatures of more than 500° C. In this case, the heat treatment need not necessarily be carried out until a metal silicide 41 with a uniform composition has formed in the interior. The heat treatment can also be terminated beforehand, so that a silicon gradient still remains over the bulk of the metal silicide 41.

Finally, as shown in FIG. 7B, the regions of the metal silicide 41 which are arranged on the upper side of the substrate and in the upper section of the trenches are removed by an isotropic etching-back. The lower section of the interior of the trenches is filled with the metal silicide 41, which later forms the top electrode of the capacitor. The further constituent parts of a DRAM are subsequently constructed in a customary manner.

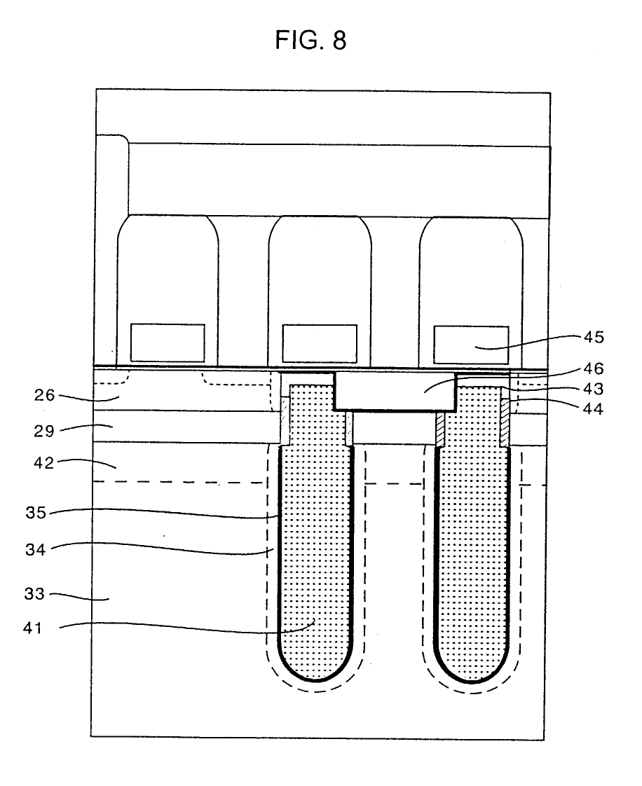

FIG. 8 is cross-sectional view taken through a possible arrangement for a DRAM. The illustration essentially corresponds to the arrangement shown in FIG. 4B. Here, too, only two storage capacitors of adjacent memory cells are illustrated for the sake of clarity. Doped regions 34 are defined in the lower layer 33 made of crystalline silicon and are electrically conductively connected to one another via doped sections 42. Toward the top side of the arrangement shown in FIG. 8, the doped sections 42 are insulated by the buried oxide layer 29, which terminates with the dielectric 35. The space defined by the dielectric 35 is filled with the metal silicide 41, which forms the top electrode of the storage capacitor. The top electrode is electrically conductively connected to the base of a field-effect transistor, arranged above the storage capacitor, via a layer 43 made of polysilicon and the doped region 44 defined in the upper silicon layer 26. The assigned storage capacitor can therefore be charged by influencing the field acting on the gate 45. Storage capacitors of adjacent memory cells are electrically insulated from one another by the oxide layer 46 arranged on the oxide layer 29.

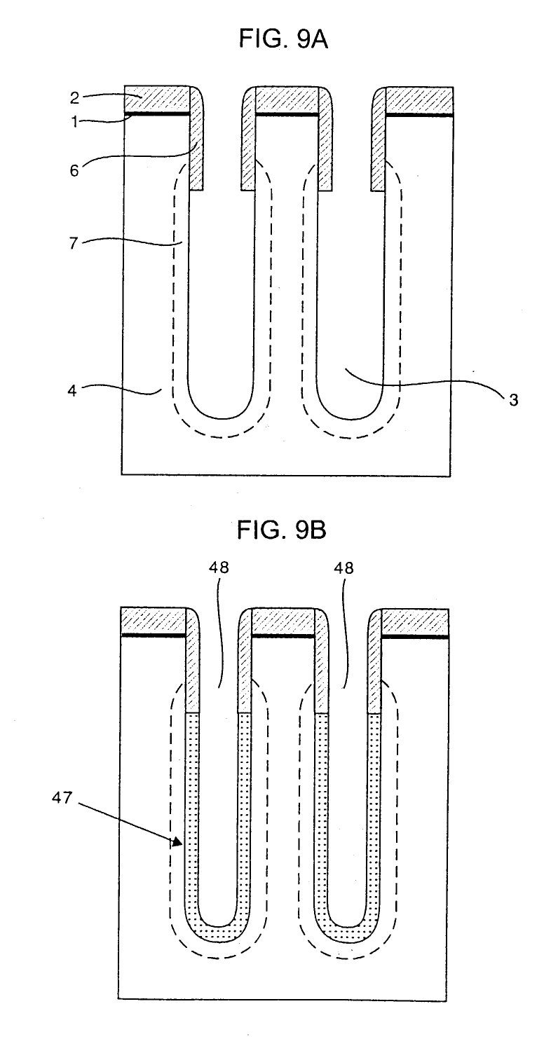

The essential steps for fabricating a bottom electrode by the inventive method are illustrated in FIGS. 9A and 9B. First, an arrangement as shown in FIG. 1A is fabricated in the manner described above. Afterward, in order to improve the electrical conductivity, that region of the wafer that adjoins the uncovered sections of the trenches 3 is doped, for example by gas phase doping with arsine. The arrangement shown in FIG. 9A is obtained. A thin oxide layer 1 and a pad nitride layer 2 are deposited on the upper side of a wafer 4. Trenches 3 are introduced into the wafer 4. The walls of upper section of each of the trenches are covered with a thin nitride/oxide layer 6 in collar form. In the lower section of the trenches 3, a doping is introduced into the silicon of the wafer 4, so that doped regions 7 having an increased electrical conductivity are obtained. The wafer 4 is electrically contact-connected, for example, using a grid that is applied on the rear side of the wafer, and is passed into an electrodeposition bath. The electrodeposition bath contains a salt of the metal to be deposited dissolved in a suitable solvent. A voltage is applied between the wafer 4 and a counterelectrode arranged in the electrodeposition bath, in order to electrodeposit a layer 47 of the metal on the electrically conductive section of the trenches, which metal forms the bottom electrode in the finished capacitor. If desired, the thin metal layer can be converted into a metal silicide in a subsequent heat treatment step in which the wafer 4 is heated to temperatures of more than 500° C. During the fabrication of the bottom electrode, the trench 3 is not completely filled with the metal 47, rather the metal 47 is only deposited on the walls of the trench 3, so that a space 48 remains in the center of the trench 3, in which space a dielectric and the top electrode can be deposited. The further construction of the capacitor and of the DRAM is then effected in the manner described for FIGS. 1B to 4B. A DRAM which includes the above-described electrodeposited bottom electrode in the storage capacitor differs from the illustration shown in FIG. 4B merely by virtue of a metal layer arranged between the conductive doped region 7 and the dielectric 8.

We claim:

1. A method for fabricating low-resistance electrodes in trench capacitors, the method which comprises:
providing a wafer;
producing trenches in the wafer;
introducing the wafer into an electrolyte solution including a salt of an electrically conductive material; and
electrically contact-connecting the wafer and applying a voltage between the wafer and a counterelectrode configured in the electrolyte solution to electrodeposit at least sections of the electrically conductive material in the trenches.

2. The method according to claim 1, wherein the trenches have an aspect ratio of at least 40.

3. The method according to claim 1, which comprises doping at least sections of the wafer adjacent the trenches to increase an electrical conductivity of the sections.

4. The method according to claim 1, which comprises introducing at least sections of an electrically conductive initial layer into the trenches before performing the step of electrodepositing at least sections of the electrically conductive material in the trenches.

5. The method according to claim 4, which comprises using a chemical vapor deposition method or an atomic layer deposition method to perform the step of introducing at least sections of the electrically conductive initial layer into the trenches.

6. The method according to claim 5, which comprises:
forming the electrically conductive initial layer from a first material;
electrodepositing a layer made of a second material on the first material; and subsequently
performing a heat treatment step such that an electrode with electrically conductive material is formed from the first material and the second material.

7. The method according to claim 4, which comprises:
forming the electrically conductive initial layer from a first material;
electrodepositing a layer made of a second material on the first material; and subsequently
performing a heat treatment step such that an electrode with electrically conductive material is formed from the first material and the second material.

8. The method according to claim 4, which comprises:
lengthening the initial layer to form a contact area; and
using the contact area when performing the step of electrically contact-connecting the wafer.

9. The method according to claim 1, which comprises:
first depositing a layer of a dielectric in the trenches, and then depositing an electrically conductive initial layer on the layer of the dielectric; and
performing the step of electrically contact-connecting the wafer by electrically contact-connecting the electrically conductive initial layer and electrodepositing the electrically conductive material on the initial layer.

10. The method according to claim 1, wherein the step of electrically contact-connecting the wafer includes electrically contact-connecting a rear side of the wafer.

11. The method according to claim 1, wherein the conductive material is a metal.
